(19) United States
(12) Patent Application Publication
(10) Pub. No.: US 2022/0261511 A1
(43) Pub. Date: Aug. 18, 2022

(54) SYSTEM, METHOD, PROGRAM, AND RECORDING MEDIUM FOR ESTIMATING DISPLACEMENT OF LONG STRUCTURE

(71) Applicant: TOKYO TECH ENGINEERING SOLUTIONS, INC., Tokyo (JP)

(72) Inventors: Yutaro UMEKAWA, Tokyo (JP); Hisatada SUGANUMA, Tokyo (JP)

(21) Appl. No.: 17/629,806

(22) PCT Filed: Jul. 26, 2019
(86) PCT No.: PCT/JP2019/029421

§ 371 Date: Jan. 25, 2022

(51) Int. Cl. G06F 30/13; G01B 21/32

(52) U.S. Cl. CPC G06F 30/13; G01B 21/32

(57) ABSTRACT

A displacement estimation system includes: accelerometers arranged with predetermined gaps therebetween in an x-axis direction corresponding to the lengthwise direction of a bridge; and a data processing device that receives, from the accelerometers, acceleration data indicating measured values of acceleration measured by the accelerometers, and estimates, based on the acceleration values in the x-axis direction indicated by the acceleration data, the relationship between a distance from a reference position in the x-axis direction and displacement from a reference orientation in a z-axis direction. Displacement of bridge at an arbitrary position in the x-axis direction can be estimated by the data processing device. Also, for each of the positions (measurement positions) at which the accelerometers are arranged, the data processing device calculates fine fluctuation components of displacement of the bridge in the z-axis direction based on the acceleration values in the z-axis direction indicated by the acceleration data, and estimates detailed displacement of the bridge at each of the measurement positions by adding the calculated fine fluctuation components to the estimated displacement in the z-axis direction.

### CROSS REFERENCE TO RELATED APPLICATIONS

This application is a U.S. National Phase Application under 35 U.S.C. 371 of International Application No. PCT/JP2019/029421, filed on Jul. 26, 2019. The entire disclosure of the above application is expressly incorporated by reference herein.

### BACKGROUND

### Technical Field

The present invention relates to technology for estimating displacement of a long structure such as a bridge or a tower.

### Related Art

It is necessary to detect the displacement of long structures such as bridges and towers. For example, if the displacement of a bridge can be detected continuously, it is possible to estimate the extent of aging deterioration of the bridge.

In one method for specifying the displacement of a structure, the distance from a reference position to a specified point on the structure is measured with use of a contactless distance meter that employs a laser beam or the like. For example, JP 2014-74685A proposes a method in which the distances to a plurality of specified points set on the lower surface of a bridge are measured with use of a contactless distance meter disposed below the bridge, and the measurement results are used to calculate and specify displacement caused by flexing of the bridge.

Methods of specifying the displacement of an object using a contactless distance meter have a problem that the longer the distance from the contactless distance meter to the object is, the lower the accuracy of the specified displacement of the object is. Methods of specifying the displacement of an object using a contactless distance meter also have a problem that the accuracy of the specified displacement of the object decreases if the contactless distance meter is shaken. Moreover, if an obstacle exists around the object, displacement of the object cannot be specified using a contactless distance meter.

In view of the above circumstances, an object of the present invention is to provide a means for estimating displacement of a long structure in various installation environments.

### SUMMARY

A first aspect of the present invention for solving the above-described problems is a system, where letting a first direction be a lengthwise direction in a reference orientation of a long structure having one or more fixed points, letting a second direction be a specified direction perpendicular to the first direction, and letting a reference plane be a plane that includes the first direction and the second direction, the system including: an acquiring means for acquiring inclination angles of the structure relative to the first direction in the reference plane, the inclination angles being measured at a specified time at a plurality of measurement positions that are at different distances from a reference position in the first direction; and a relationship estimating means for estimating, with use of the inclination angles acquired by the acquiring means, a relationship between distance from the reference position in the first direction and displacement of the structure from the reference orientation in the reference plane at a position separated from the reference position by the distance.

According to the system pertaining to the first aspect, if the inclination angle of a long structure can be measured at a plurality of measurement positions, the displacement of the structure can be estimated regardless of the installation environment of the structure.

As a second aspect, the system according to the first aspect may have a configuration in which for each of the measurement positions, the acquiring means acquires time-series values of acceleration of the structure in the first direction measured at the measurement position, extracts components having a frequency less than or equal to a predetermined threshold value from a waveform expressed by the acquired time-series values, and acquires the inclination angle of the structure at the measurement position based on the extracted components.

According to the system pertaining to the second aspect, it is possible to reduce the number of inclination angle measurement positions required to estimate the relationship between position and displacement.

As a third aspect, the system according to the first or second aspect may have a configuration in which the acquiring means acquires the inclination angles for each of a plurality of different times, the relationship estimating means estimates the relationship for each of the different times, and the system further includes: a displacement time-series value specifying means for specifying time-series values of displacement of the structure from the reference orientation at a specified position in the first direction with use of the relationships estimated by the relationship estimating means for the different times.

According to the system pertaining to the third aspect, it is possible to determine change over time in the displacement of a long structure at a specified position.

As a fourth aspect, the system according to the third aspect may have a configuration in which the acquiring means acquires time-series values of acceleration of the structure in the second direction measured at a specified measurement position in the first direction, the system further includes: an extracting means for extracting components having a frequency greater than or equal to a predetermined threshold value from a waveform expressed by the time-series values of acceleration of the structure acquired by the acquiring means; and a calculating means for calculating an integral of the acceleration components extracted by the extracting means and calculating time-series values of a fine fluctuation component of displacement of the structure in the second direction at the specified measurement position, and the displacement time-series value specifying means corrects the time-series values of displacement that were specified using the relationships estimated by the relationship estimating means, by adding, to the specified time-series values of displacement, the time-series values of a fine fluctuation component of displacement that were calculated by the calculating means.

According to the system pertaining to the fourth aspect, it is possible to determine detailed change over time in displacement of a long structure at a specified position.

As a fifth aspect, the system according to any of the first to fourth aspects may have a configuration in which letting a third direction be a specified direction that is perpendicular to the first direction and different from the second direction, letting the reference plane be a first reference plane, and letting a second reference plane be a plane that includes the first direction and the third direction, for each of the measurement positions, the acquiring means acquires the inclination angle of the structure in the second reference plane relative to the first direction that was measured at the specified timing, and the relationship estimating means uses the inclination angles in the first reference plane acquired by the acquiring means and the inclination angles in the second reference plane acquired by the acquiring means to specify inclination angles of the structure relative to the first direction in a specified plane that includes the first direction, and, based on the specified inclination angles, estimates a relationship between distance from the reference position in the first direction and displacement of the structure from the reference orientation in the specified plane at a position that is separated from the reference position by the distance.

According to the system pertaining to the fifth aspect, even if deformation of a long structure is not limited to deformation in one direction perpendicular to the axis of the structure, it is possible to estimate the three-dimensional shape of the structure at the time of measurement.

As a sixth aspect, the system according to any of the first to fifth aspects may have a configuration in which the acquiring means acquires time-series values of the inclination angle, and the relationship estimating means performs correction for error included in the inclination angles acquired by the acquiring means based on a statistic of the inclination angles in a time period in which the time-series values of the inclination angle acquired by the acquiring means fluctuate within a predetermined range, and estimates the relationship with use of the corrected inclination angles.

According to the system pertaining to the sixth aspect, even if the measured values of the inclination angle are influenced by a disturbance such as a temperature disturbance, it is possible to estimate an accurate relationship between position and displacement from which such influence has been removed.

A seventh aspect of the present invention is a method, where letting a first direction be a lengthwise direction in a reference orientation of a long structure having one or more fixed points, letting a second direction be a specified direction perpendicular to the first direction, and letting a reference plane be a plane that includes the first direction and the second direction, the method including: a step of acquiring inclination angles of the structure relative to the first direction in the reference plane, the inclination angles being measured at a specified time at a plurality of measurement positions that are at different distances from a reference position in the first direction; and a step of estimating, with use of the inclination angles acquired in the acquiring step, a relationship between distance from the reference position in the first direction and displacement of the structure from the reference orientation in the reference plane at a position separated from the reference position by the distance.

According to the method pertaining to the seventh aspect, if the inclination angle of a long structure can be measured at a plurality of measurement positions, displacement of the structure can be estimated regardless of the installation environment of the structure.

An eighth aspect of the present invention is a program, where letting a first direction be a lengthwise direction in a reference orientation of a long structure having one or more fixed points, letting a second direction be a specified direction perpendicular to the first direction, and letting a reference plane be a plane that includes the first direction and the second direction, the program causing a computer to execute: processing of acquiring inclination angles of the structure relative to the first direction in the reference plane, the inclination angles being measured at a specified time at a plurality of measurement positions that are at different distances from a reference position in the first direction; and processing of estimating, with use of the inclination angles acquired in the acquiring processing, a relationship between distance from the reference position in the first direction and displacement of the structure from the reference orientation in the reference plane at a position separated from the reference position by the distance.

A ninth aspect of the present invention is a computer-readable recording medium having non-transitorily recorded thereon a program, where letting a first direction be a lengthwise direction in a reference orientation of a long structure having one or more fixed points, letting a second direction be a specified direction perpendicular to the first direction, and letting a reference plane be a plane that includes the first direction and the second direction, the program causing a computer to execute: processing of acquiring inclination angles of the structure relative to the first direction in the reference plane, the inclination angles being measured at a specified time at a plurality of measurement positions that are at different distances from a reference position in the first direction; and processing of estimating, with use of the inclination angles acquired in the acquiring processing, a relationship between distance from the reference position in the first direction and displacement of the structure from the reference orientation in the reference plane at a position separated from the reference position by the distance.

According to the program pertaining to the eighth aspect and the recording medium pertaining to the ninth aspect, if the inclination angle of a long structure can be measured at a plurality of measurement positions, displacement of the structure can be estimated with use of a computer regardless of the installation environment of the structure.

### Advantageous Effects of Invention

According to the present invention, it is possible to estimate displacement of a long structure in various installation environments.

### BRIEF EXPLANATION OF THE DRAWINGS

FIGS. 1(A) and 1(B) are diagrams showing an overall configuration of a displacement estimation system according to an embodiment.

FIG. 2 is a diagram showing a configuration of a computer used for realizing a data processing device according to an embodiment.

FIG. 3 is a diagram showing a configuration of the data processing device according to an embodiment.

FIG. 4 is a diagram showing a sequence of processing executed by the displacement estimation system according to an embodiment.

FIG. 5 is an example of a graph showing a waveform expressed by time-series values of a deflection angle generated by the displacement estimation system according to an embodiment.

FIG. 6 is an example of a graph showing a waveform (after drift elimination) expressed by time-series values of a deflection angle generated by the displacement estimation system according to an embodiment.

FIG. 7 is an example of a graph showing the relationship between a deflection angle extracted by the displacement estimation system according to an embodiment and the distance from a reference position to a measurement position in the x axis direction.

FIG. 8 is an example of a graph showing the relationship between distance and displacement, which is estimated by the displacement estimation system according to an embodiment.

FIG. 9 is a diagram showing a sequence of processing executed by the displacement estimation system according to an embodiment.

FIG. 10 is a diagram showing a sequence of processing executed by the displacement estimation system according to an embodiment.

FIG. 11 is an example of a graph showing time-series values of displacement specified by the displacement estimation system according to an embodiment.

FIG. 12 is an example of a graph showing time-series values of a fine fluctuation component of displacement specified by the displacement estimation system according to an embodiment.

FIG. 13 is an example of a graph showing time-series values of displacement corrected by addition of fine fluctuation components by the displacement estimation system according to an embodiment.

FIGS. 14(A)-14(C) show graphs comparing estimated values of displacement estimated by the displacement estimation system according to an embodiment and measured values of displacement obtained by a displacement meter.

FIGS. 15(A) and 15(B) are diagrams showing an overall configuration of a displacement estimation system according to a variation.

FIGS. 16(A)-16(D) are examples of graphs showing time-series values of displacement estimated by the displacement estimation system according to a variation.

FIG. 17 is a diagram for describing a method in which the displacement estimation system according to a variation calculates vertical displacement at a measurement position on a structure whose lengthwise direction is the vertical direction.

### DETAILED DESCRIPTION

The following describes displacement estimation system 1 according to an embodiment of the present invention. Displacement estimation system 1 is a system that estimates displacement at each of a plurality of positions on a long structure that deforms when subjected to external force.

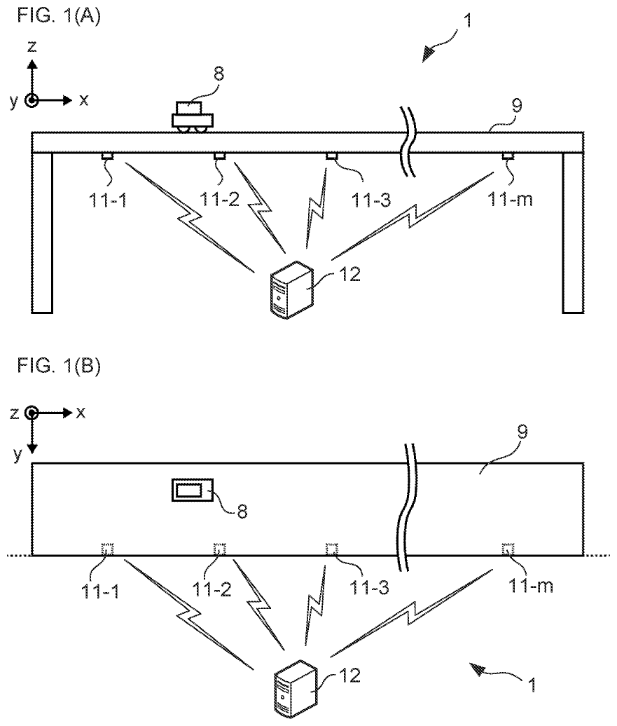

FIGS. 1(A) and 1(B) are diagrams showing the overall configuration of displacement estimation system 1. In the example of FIGS. 1(A) and 1(B), displacement estimation system 1 is used to estimate displacement of bridge 9 (an example of a long structure). For example, when vehicle 8 travels on bridge 9, bridge 9 deforms when subjected to a load caused by the weight of vehicle 8. FIG. 1(A) is a side view of bridge 9, and FIG. 1(B) is a view of bridge 9 from above.

As shown in FIGS. 1(A) and 1(B), in the following description, the lengthwise direction of bridge 9 is the x-axis direction (the rightward direction in FIGS. 1(A) and 1(B) is the positive direction), the vertical direction is the z-axis direction (the upward direction in FIG. 1(A) is the positive direction), and the direction perpendicular to the x-axis direction and the z-axis direction is the y-axis direction (the downward direction in FIG. 1(B) is the positive direction). Also, the left end of bridge 9 in FIGS. 1(A) and 1(B) is set as the reference position (x=0) in the x-axis direction. Also, the reference orientation of bridge 9 refers to the position of the lower surface of the superstructure of bridge 9 (the surface on which later-described accelerometers 11 are disposed) in a reference plane denoted by R in FIG. 1(B) (a plane that is perpendicular to the y-axis direction and includes the positions where accelerometers 11 are disposed) when bridge 9 is not subjected to external force.

Displacement estimation system 1 includes in accelerometers 11 and data processing device 12 that performs data communication with each of the in accelerometers 11. Accelerometers 11 are each a 3-axis accelerometer, for example. Note that in the present embodiment, measured values of acceleration in the x-axis direction (an example of the first direction) and the z-axis direction (an example of the second direction) are used, but measured values of acceleration in the y-axis direction are not used, and therefore 2-axis accelerometers may be used as accelerometers 11. Hereinafter, suffix numbers will be added when distinguishing between the in accelerometers 11, such as accelerometers 11-1 to 11-m.

The in accelerometers 11 includes accelerometer 11-1, accelerometer 11-2, . . . , and accelerometer 11-m that are disposed side by side in the stated order with predetermined gaps therebetween in the x-axis direction on the lower surface of the superstructure of bridge 9. As described above, in accelerometers 11 are installed in reference plane R. The positions where accelerometers 11-1 to 11-m are disposed are hereinafter referred to as measurement positions P1 to Pm.

The in accelerometers 11 each successively transmit acceleration data, which indicates measured values of continuously measured acceleration, to data processing device 12 by wireless communication, for example.

Data processing device 12 receives the acceleration data continuously transmitted by each of accelerometers 11, and uses the received acceleration data to estimate a relational expression that can roughly specify displacement from the reference orientation at an arbitrary position on bridge 9 in the x-axis direction, and to also make a detailed estimation of displacement from the reference orientation at each of measurement positions P1 to Pm.

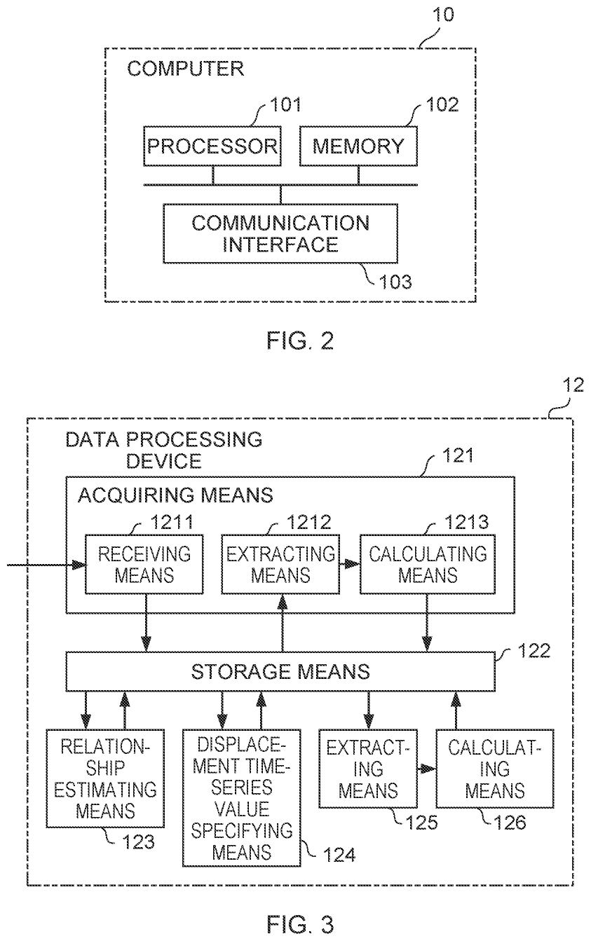

In the present embodiment, data processing device 12 is realized by a computer. Specifically, the computer functions as data processing device 12 by executing processing in accordance with a program pertaining to the present embodiment. FIG. 2 is a diagram showing the configuration of computer 10 used for realizing data processing device 12. Computer 10 includes processor 101 that performs various types of data processing in accordance with a program, memory 102 that stores various types of data including the program, and communication interface 103 that performs data communication with an external device.

FIG. 3 is a diagram showing the configuration of data processing device 12. When computer 10 executes processing in accordance with the program pertaining to the present embodiment, data processing device 12 that includes the constituent elements shown in FIG. 3 is realized. The constituent elements of data processing device 12 will be described below.

Acquiring means 121 is mainly realized by communication interface 103 and processor 101 under the control of processor 101, and acquires the inclination angles of reference plane R of bridge 9 relative to the x-axis direction at measurement positions P1 to Pm, which are measured at a specified timing. In the present embodiment, acquiring means 121 calculates the inclination angles based on acceleration in the x-axis direction measured by accelerometers 11. To achieve this, acquiring means 121 includes receiving means 1211 that receives the acceleration data transmitted by accelerometers 11, extracting means 1212 that extracts components having a frequency less than or equal to a predetermined threshold value from a waveform expressed by time-series values of acceleration in the x-axis direction at measurement positions P1 to Pm indicated by the acceleration data, and calculating means 1213 for calculating the inclination angle of bridge 9 at each of measurement positions P1 to Pm based on the acceleration components extracted by extracting means 1212. Receiving means 1211 is mainly realized by communication interface 103 under the control of processor 101. Also, extracting means 1212 and calculating means 1213 are mainly realized by processor 101.

Storage means 122 is mainly realized by memory 102 under the control of processor 101, and stores various types of data. The data stored by storage means 122 includes data generated by constituent elements of data processing device 12, such as acceleration data received by receiving means 1211 from accelerometers 11 and data indicating the inclination angles calculated by calculating means 1213.

Relationship estimating means 123 is mainly realized by processor 101, and uses the inclination angles acquired by acquiring means 121 to estimate the relationship between distance from the reference position in the x-axis direction and displacement of bridge 9 from the reference orientation in reference plane R at a position separated from the reference position by the distance. The relationship estimated by relationship estimating means 123 can be used to specify rough displacement from the reference orientation at an arbitrary position (not limited to measurement positions P1 to Pm) on bridge 9 in the x-axis direction.

Displacement time-series value specifying means 124 is realized mainly by processor 101, and uses the relationship estimated by relationship estimating means 123 for each of a plurality of different times to specify time-series values of displacement of bridge 9 from the reference orientation at a specified position in the x-axis direction.

Extracting means 125 is mainly realized by processor 101 and extracts components having a frequency greater than or equal to a predetermined threshold value from a waveform expressed by time-series values of acceleration in the z-axis direction at each of measurement positions P1 to Pm (an example of a specified position in the x-axis direction), which are obtained from the acceleration data received by receiving means 1211.

Calculating means 126 is mainly realized by processor 101, calculates the integral of the acceleration components extracted by extracting means 125, and calculates time-series values of a fine fluctuation component of displacement of bridge 9 in the z-axis direction at each of measurement positions P1 to Pm. The time-series values of a fine fluctuation component of displacement calculated by calculating means 126 are added by displacement time-series value specifying means 124 to the rough displacement of bridge 9 from the reference orientation at each of measurement positions P1 to Pm, that is to say are added to the time-series values of rough displacement in the z-axis direction. Due to this addition, it is possible to determine the time-series values of detailed displacement of bridge 9 at measurement positions P1 to Pm.

Next, processing performed by displacement estimation system 1 will be described. First, receiving means 1211 continuously receives the acceleration data transmitted by each of accelerometers 11. The acceleration data received by receiving means 1211 is stored in storage means 122.

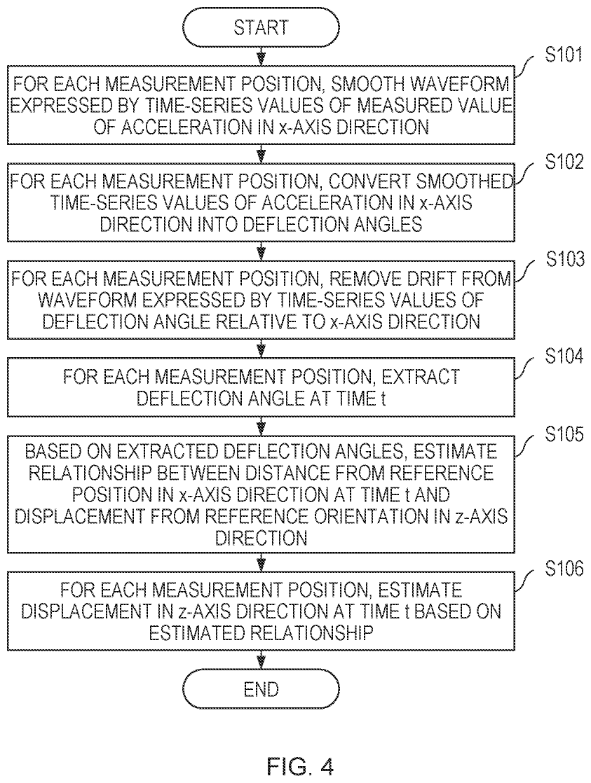

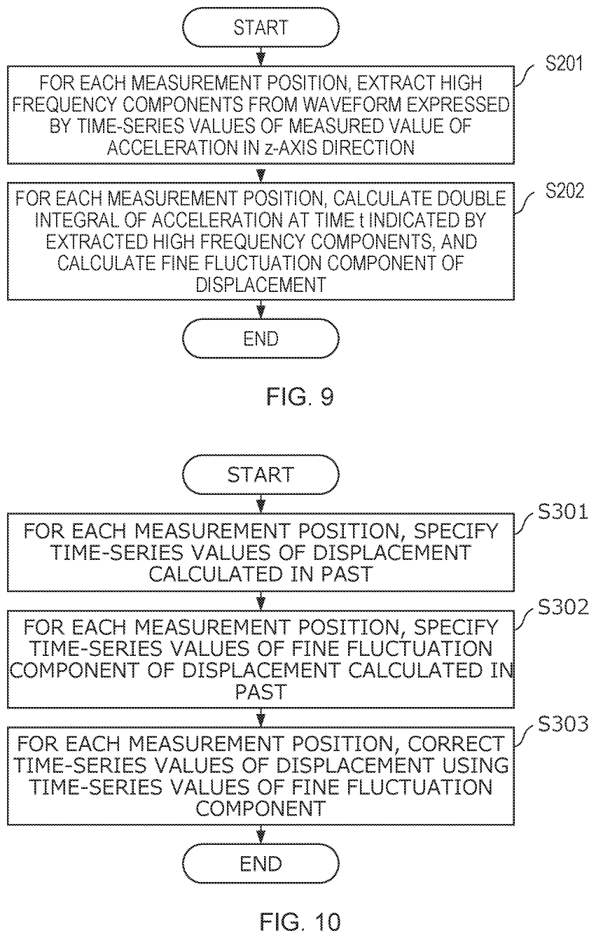

In parallel with the above-mentioned processing for receiving and storing the acceleration data, displacement estimation system 1 executes processing in accordance with the sequences shown in FIGS. 4 and 9 below each time a predetermined time period elapses.

FIG. 4 shows the sequence of a portion of the processing performed by the displacement estimation system 1 each time a predetermined time period elapses, specifically the portion of processing for estimating rough displacement of bridge 9 from the reference orientation at an arbitrary position (including measurement positions P1 to Pm) in the x-axis direction.

First, for each of measurement positions P1 to Pm, extracting means 1212 reads out the acceleration data for a most recent period T having a predetermined time length from storage means 122, and smoothes the waveform expressed by the time-series values of measured values of acceleration in the x-axis direction indicated by the acceleration data (step S101). For example, extracting means 1212 smoothes the waveform expressed by the time-series values of acceleration by passing the waveform through a low-pass filter to extract components having a frequency less than or equal to a predetermined threshold value (cutoff frequency).

Next, for each of measurement positions P1 to Pm, calculating means 1213 calculates the inclination angle of bridge 9 relative to the x-axis direction based on the time-series values of measured values of acceleration in the x-axis direction resulting from smoothing in step S101 (step S102). The inclination angle relative to the x-axis direction at the measurement position of bridge 9 is an inclination angle caused by flexure of bridge 9. Hereinafter, the inclination angle at a measurement position on a structure due to flexure of the structure will be referred to as the “deflection angle”. Note that letting Aₓ be the acceleration of bridge 9 in the x-axis direction at a certain position, the acceleration in the z-axis direction can be denoted as gravitational acceleration G, and therefore deflection angle φ of bridge 9 relative to the x-axis direction at the certain position is calculated according to Expression 1 shown below.

$$φ = a sin ( \frac{{A}_{x}}{G} ) \qquad Expression 1$$

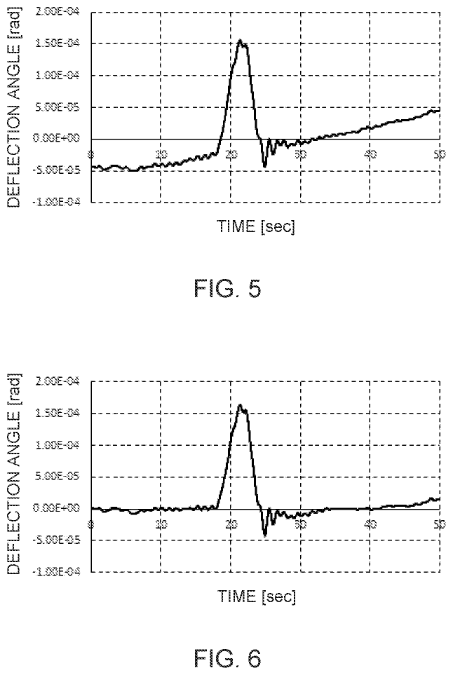

FIG. 5 is an example of a waveform expressing the time-series values of the deflection angle of bridge 9 in the x-axis direction at a certain measurement position, which are generated by the processing of step S102.

Next, for each of measurement positions P1 to Pm, relationship estimating means 123 specifies drift from the waveform expressed by the time-series values of the deflection angle calculated in step S102, and removes the specified drift from the waveform (step S103). Note that the deflection angle drift specified in step S103 refers to deviation from the actual deflection angle that occurs in a deflection angle calculated from the measured value of acceleration due to deviation from the actual acceleration that occurs in a measured value obtained by accelerometer 11 caused by the influence of a disturbance such as a temperature disturbance.

For example, in the case of the waveform indicated by the time-series values of the deflection angle calculated in step S102 (see FIG. 5), relationship estimating means 123 specifies, as a straight line indicating drift, a straight line that approximates the waveform in a period in which the deflection angle is stable in the vicinity of 0. FIG. 6 shows an example of a graph of a waveform (after drift removal) indicated by the time-series values of the deflection angle of bridge 9 in the x-axis direction at a certain measurement position, which were generated by the processing of step S103.

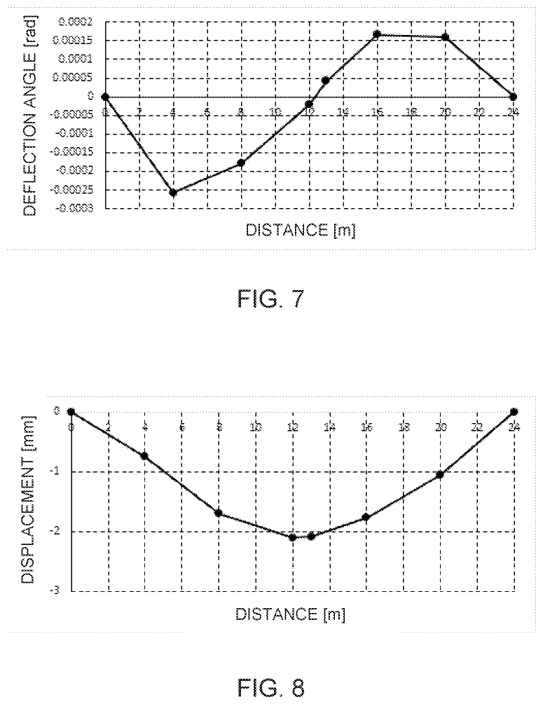

Next, for each of measurement positions P1 to Pm, relationship estimating means 123 extracts the deflection angle at a specified time t (e.g., the time when T/2 has elapsed from the start of period T) from the time-series values of the deflection angle after drift removal, which were generated in step S103 (step S104). FIG. 7 shows an example of a graph showing the relationship between the deflection angle extracted in step S104 and the distance from the reference position to the measurement position in the x-axis direction.

Next, based on the deflection angles at measurement positions P1 to Pm at time t that were extracted in step S104 and the distances from the reference position to measurement positions P1 to Pm in the x-axis direction, relationship estimating means 123 estimates the relationship between distance x from the reference position in the x-axis direction and displacement δ(x) of bridge 9 from the reference orientation at the corresponding position at time t (step S105).

The following describes a method by which relationship estimating means 123 estimates displacement δ(x), which is a function of the distance x, in step S105.

Letting φ(x) be the deflection angle at the position that is the distance x from the reference position in the x-axis direction, the displacement δ(x) of bridge 9 from the reference orientation in the x-axis direction is the integral of the deflection angle φ(x), which is calculated by Expression 2 shown below.

δ(x)=∫φ(x)dx Expression 2

The deflection angle φ(x) of the entire girder of bridge 9 can be approximated by the nth-degree polynomial function shown in Expression 3 shown below, for example.

φ(x)=a₁xⁿ+a₂xⁿ⁻¹+a₃xⁿ⁻²+ . . . +aₙ₊₁ Expression 3

Based on Expressions 2 and 3, the displacement δ(x) is approximated by Expression 4 shown below.

$$δ ( x ) = \frac{{a}_{1}}{n + 1} {x}^{n + 1} + \frac{{a}_{2}}{n} {x}^{n} + \frac{{a}_{3}}{n - 1} {x}^{n - 1} + … + {a}_{n + 1} x + {a}_{n + 2} \qquad Expression 4$$

Accordingly, for time t, letting xᵢ be the distance from the reference position to measurement position Pi (i=1, 2, . . . , M) in the x-axis direction, and letting φᵢ be the deflection angle at measurement position Pi, the least squares method is used to calculate the coefficient of each degree in above Expression 4, as shown by the determinant in Expression 5 shown below.

$$[ \begin{matrix}{a}_{1} \\ {a}_{2} \\ ⋮ \\ {a}_{n} \\ {a}_{n + 1}\end{matrix} ] = {[ \begin{matrix}{x}_{1}^{n} & {x}_{1}^{n - 1} & … & {x}_{1} & 1 \\ ⋮ & ⋮ & ⋱ & ⋮ & ⋮ \\ {x}_{m}^{n} & {x}_{m}^{n - 1} & … & {x}_{m} & 1\end{matrix} ]}^{- 1} \qquad Expression 5$$

Accordingly, the coefficient of each degree is calculated by the above determinant in Expression 5, and the relationship between the distance x and the displacement δ(x) is estimated. FIG. 8 shows an example of a graph showing the relationship between distance and displacement at time t, which was estimated in step S105. Relationship data indicating the relationship between distance and displacement at time t estimated in step S105 is stored in storage means 122.

Returning to FIG. 4, the following is a continuation of the description of processing performed by displacement estimation system 1. Next, using the relationship between the distance x and the displacement δ(x) estimated in step S105 for each of measurement positions P1 to Pm, displacement time-series value specifying means 124 calculates the displacement of bridge 9 from the reference orientation at each of measurement positions P1 to Pm at time t (step S106).

Specifically, letting δ(x) be a function representing the displacement estimated in step S105, and letting xi be the distance from the reference position to measurement position Pi (i=1, 2, . . . , M) in the x-axis direction, displacement time-series value specifying means 124 calculates displacement δᵢ of bridge 9 from the reference orientation at measurement position Pi at time t using the determinant in Expression 6 shown below.

$$[ \begin{matrix}{δ}_{1} \\ ⋮ \\ {δ}_{m}\end{matrix} ] = [ \begin{matrix}\frac{{x}_{1}^{n + 1}}{n + 1} & \frac{{x}_{1}^{n}}{n} & … & \frac{{x}_{1}^{2}}{2} & {x}_{1} \\ ⋮ & ⋮ & ⋱ & ⋮ & ⋮ \\ \frac{{x}_{m}^{n + 1}}{n + 1} & \frac{{x}_{m}^{n}}{n} & … & \frac{{x}_{m}^{2}}{2} & {x}_{m}\end{matrix} ] [ \begin{matrix}{a}_{1} \\ {a}_{2} \\ ⋮ \\ {a}_{n} \\ {a}_{n + 1}\end{matrix} ] \qquad Expression 6$$

Displacement data indicating the displacement at time t calculated for each of measurement positions P1 to Pm in step S106 is stored in storage means 122.

FIG. 9 shows the sequence of a portion of the processing performed by displacement estimation system 1 each time a predetermined time period elapses, specifically the portion of processing for calculating the fine fluctuation component of the displacement of bridge 9 from the reference orientation at measurement positions P1 to Pm.

First, for each of measurement positions P1 to Pm, extracting means 125 reads out the acceleration data for a most recent period T having a predetermined time length from storage means 122, and extracts high frequency components from the waveform expressed by the time-series values of measured values of acceleration in the z-axis direction indicated by the acceleration data (step S201). For example, extracting means 125 passes the waveform indicated by the time-series values of acceleration through a high-pass filter to extract components having a frequency greater than or equal to a predetermined threshold value (cutoff frequency).

Next, for each of measurement positions P1 to Pm, calculating means 126 calculates the double integral, at time t, of the high frequency components of the waveform expressed by the time-series values of acceleration in the z-axis direction that were extracted in step S201, and calculates the fine fluctuation component of displacement of bridge 9 from the reference orientation at time t (step S202). Displacement fine fluctuation component data that indicates the fine fluctuation components of displacement at time t calculated for each of measurement positions P1 to Pm in step S202 is stored in storage means 122.

Displacement estimation system 1 executes processing in accordance with the sequence shown in FIG. 10 each time a predetermined time period elapses, for example.

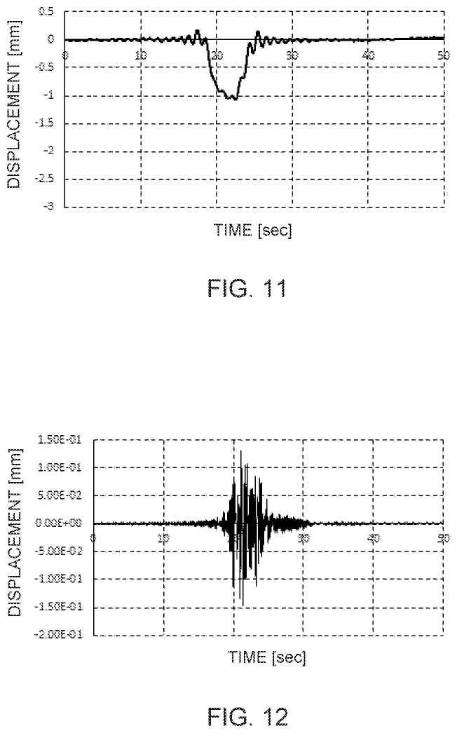

First, for each of measurement positions P1 to Pm, displacement time-series value specifying means 124 reads out, from storage means 122, displacement data indicating the rough displacement of bridge 9 that was calculated in step S106 for a past period U having a predetermined time length, and specifies the time-series values of displacement indicated by the displacement data that was read out (step S301). FIG. 11 shows an example of a graph showing the time-series values of displacement of bridge 9 from the reference orientation at a certain measurement position, which were specified in step S301.

Next, for each of measurement positions P1 to Pm, displacement time-series value specifying means 124 reads out, from storage means 122, displacement fine fluctuation component data that indicates the fine fluctuation component of displacement of bridge 9 that was calculated in step S202 for past period U having a predetermined time length, and specifies the time-series values of the fine fluctuation component of displacement indicated by the fine fluctuation component data that was read out (step S302). FIG. 12 shows an example of a graph showing the time-series values of the fine fluctuation component of displacement of bridge 9 from the reference orientation at a certain measurement position, which were specified in step S302.

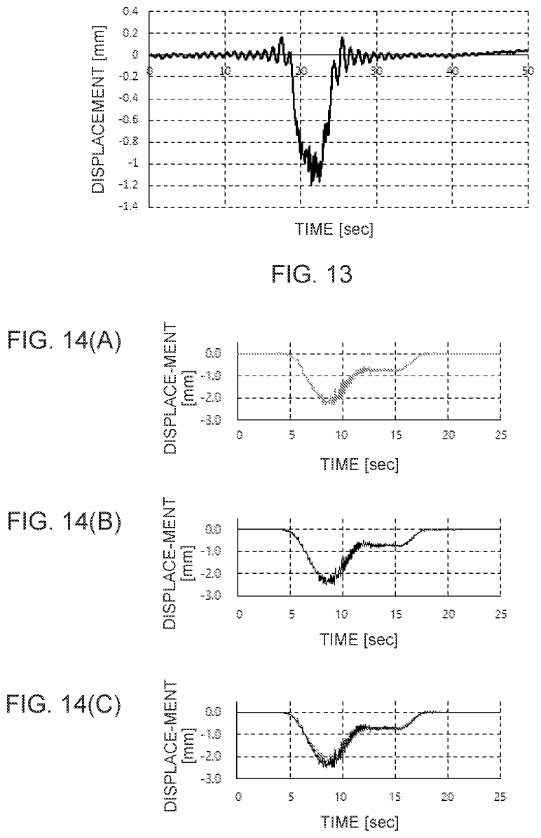

Next, for each of measurement positions P1 to Pm, displacement time-series value specifying means 124 adds the time-series values of the fine fluctuation component of displacement that were specified in step S302 to the time-series values of displacement that were specified in step S301 so as to correct the time-series values of displacement specified in step S301 (step S303). FIG. 13 shows an example of a graph showing the time-series values of displacement of bridge 9 from the reference orientation at a certain measurement position, which were corrected by the addition of the fine fluctuation components in step S303. Displacement time-series data indicating the time-series values of displacement that were corrected for each of measurement positions P1 to Pm in step S303 is stored in storage means 122.

As described above, according to displacement estimation system 1, it is possible to estimate rough displacement of a long structure from a reference orientation at an arbitrary position in the lengthwise direction at a specified time t. Also, according to displacement estimation system 1, it is possible to estimate detailed displacement of a long structure from a reference orientation at a specified position (measurement position) in the lengthwise direction at a specified time t.

FIGS. 14(A)-14(C) show graphs in which measured values of displacement of bridge 9 from the reference orientation at a certain measurement position measured by a displacement meter are compared with estimated values of displacement of bridge 9 from the reference orientation at the same measurement position estimated by displacement estimation system 1. FIG. 14(A) shows the time-series values of measured values of displacement measured by the displacement meter. FIG. 14(B) shows the time-series values of estimated values of displacement estimated by displacement estimation system 1. FIG. 14(C) shows the graph of FIG. 14(A) and the graph of FIG. 14(B) superimposed on each other. It can be seen from the graphs in FIGS. 14(A)-14(C) that the displacement estimated by displacement estimation system 1 matches well with the displacement measured by the displacement meter.

### Variations]

The embodiment described above can be modified in various ways within the scope of the technical idea of the present invention. Examples of such variations are shown below. Note that two or more of the following variations may be combined.

(1) In the above-described embodiment, displacement estimation system 1 measures the acceleration in the x-axis direction using accelerometers 11 and calculates the deflection angle (inclination angle relative to the x-axis direction) of bridge 9 based on the measured acceleration values (step S102). Alternatively, displacement estimation system 1 may be provided with tilt meters disposed at measurement positions P1 to Pm, and directly measure the deflection angle using the inclination angles measured by the tilt meters. In the case of this variation, displacement estimation system 1 uses the measured values of the inclination angle measured by the tilt meters in the processing of step S103.

(2) In the above-described embodiment, displacement estimation system 1 estimates the displacement of a long structure that has two fixed points, as shown in FIGS. 1(A) and 1(B). The structure for which the displacement estimation system according to the present invention estimates displacement is not limited to having two fixed points, and may have one fixed point or three or more fixed points. Also, the structure for which the displacement estimation system according to the present invention estimates displacement is not limited to being a bridge type of structure. Furthermore, the lengthwise direction of the structure for which the displacement estimation system according to the present invention estimates displacement is not limited to being the horizontal direction.

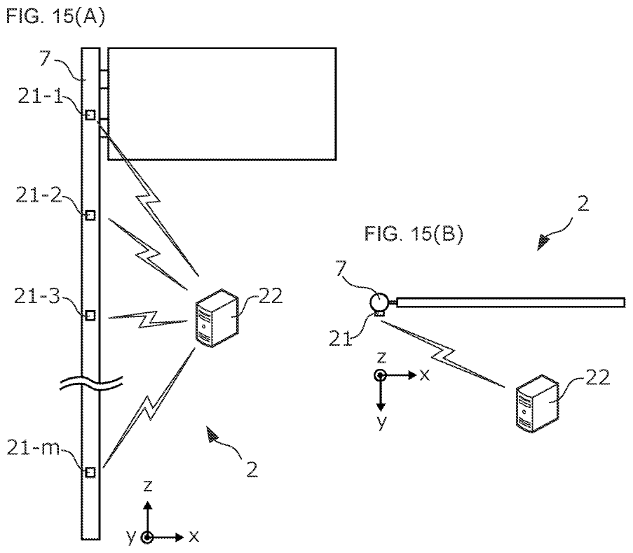

FIGS. 15(A) and 15(B) are diagrams showing the overall configuration of displacement estimation system 2 used to estimate the displacement of sign pole 7. FIG. 15(A) is a side view of sign pole 7, and FIG. 15(B) is a top view of sign pole 7. Sign pole 7 is a long structure that has a lower end that is fixed to the ground and has a sign attached near the upper end, and also has the vertical direction as its lengthwise direction. Sign pole 7 has one fixed point.

Data processing device 12 includes a plurality of accelerometers 21 arranged with predetermined gaps therebetween in the lengthwise direction (z-axis direction) of sign pole 7, and data processing device 22 that receives, from accelerometers 21, acceleration data indicating the acceleration values measured by accelerometers 21 and estimates displacement of sign pole 7 from a reference orientation with use of the received acceleration data.

Accelerometers 21 are each a 3-axis accelerometer and measure acceleration in the x-axis direction, the y-axis direction (an example of the third direction), and the z-axis direction. Unlike data processing device 12, data processing device 22 estimates displacement in the x-axis direction and the y-axis direction instead of displacement in the z-axis direction. Data processing device 22 estimates displacement in the x-axis direction and the y-axis direction by performing processing similar to that when data processing device 12 estimates displacement in the z-axis direction.

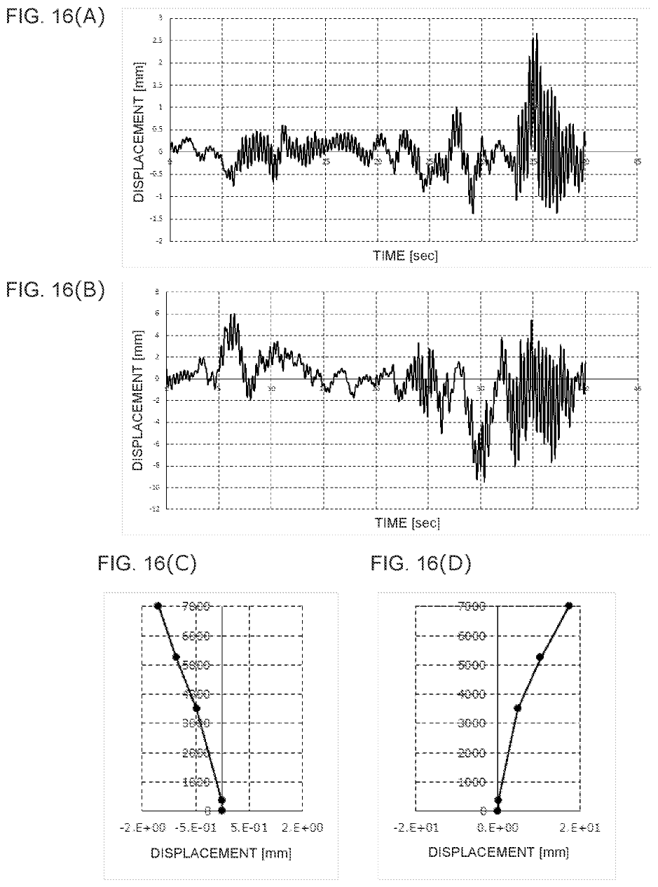

FIGS. 16(A)-16(D) show examples of graphs showing time-series values of displacement of sign pole 7. FIG. 16(A) shows time-series values of displacement of sign pole 7 from a reference orientation in the x-axis direction at a certain measurement position. FIG. 16(B) shows time-series values of displacement of sign pole 7 from a reference orientation in the y-axis direction at a certain measurement position. FIG. 16(C) is a graph showing the relationship between distance from a reference position in the z-axis direction and displacement in the x-axis direction of sign pole 7 at a certain time. FIG. 16(D) is a graph showing the relationship between distance from a reference position in the z-axis direction and displacement in the y-axis direction of sign pole 7 at a certain time.

As described above, according to displacement estimation system 2, the three-dimensional shape of a long structure at a certain time can be estimated.

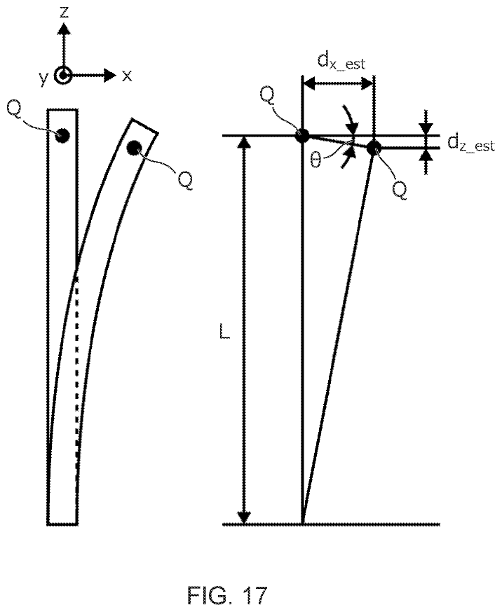

Also, displacement estimation system 2 may calculate displacement in the z-axis direction at a measurement position (point Q in FIG. 17) using the displacement values of sign pole 7 in the x-axis direction and the y-axis direction that were estimated as described above. For example, in the case where sign pole 7 flexes in the x-axis direction as shown in FIG. 17 at a certain time, point Q moves by dₓ in the x-axis direction from the position in the reference orientation, and accelerometer 21 located at the measurement position measures an inclination angle θ relative to the vertical direction, then displacement d_{z} (absolute value) of point Q in the z-axis direction is calculated using Expression 7 shown below.

d_{z}=dₓ*tan θ Expression 7

(3) In the above-described embodiment, accelerometers 11 and data processing device 12 of displacement estimation system 1 perform data communication wirelessly, but the method by which accelerometers 11 and data processing device 12 perform data communication is not limited to being wireless communication, and these devices may perform wired data communication.

(4) In the above-described embodiment, relationship estimating means 123 approximates the deflection angle of the entire girder of bridge 9 using a polynomial function that has the distance x from the reference position in the x-axis direction as a variable. However, the type of function by which relationship estimating means 123 approximates the deflection angle of the structure is not limited to being a polynomial function. For example, an exponential function, a logarithmic function, or the like may be adopted instead of the polynomial function.

(5) In the above-described embodiment, data processing device 12 is realized by a computer that executes processing in accordance with a program. Alternatively, data processing device 12 may be configured as a so-called dedicated device.

(6) In the above-described embodiment, the program executed by computer 10 to realize data processing device 12 may be downloaded to computer 10 via a network such as the Internet, or may be distributed in the form of being non-transitorily recorded on a recording medium and be read from the recording medium to computer 10.

1. A system comprising a processor, where letting a first direction be a lengthwise direction in a reference orientation of a long structure having one or more fixed points, letting a second direction be a specified direction perpendicular to the first direction, and letting a reference plane be a plane that includes the first direction and the second direction,
wherein the processor is configured to execute
acquiring inclination angles of the structure relative to the first direction in the reference plane, the inclination angles being measured at each of a plurality of different times at a plurality of measurement positions, the plurality of measurement positions being at different distances from a reference position in the first direction;
estimating, with use of the acquired inclination angles, a relationship between distance from the reference position in the first direction and displacement of the structure from the reference orientation in the reference plane at a position separated from the reference position by the distance, for each of the plurality of different times;
specifying time-series values of displacement of the structure from the reference orientation at a specified position in the first direction with use of the estimated relationship for each of the plurality of different times;
acquiring time-series values of acceleration of the structure in the second direction measured at a specified measurement position in the first direction;
extracting components having a frequency greater than or equal to a predetermined threshold value from a waveform expressed by the acquired time-series values of acceleration;
calculating an integral of the components extracted from the waveform to calculate time-series values of a fine fluctuation component of displacement of the structure in the second direction at the specified measurement position; and
correcting the time-series values of displacement that were specified using the estimated relationships, by adding, to the specified time-series values of displacement, the calculated time-series values of a fine fluctuation component of displacement.

2-6. (canceled)

7. A method, where letting a first direction be a lengthwise direction in a reference orientation of a long structure having one or more fixed points, letting a second direction be a specified direction perpendicular to the first direction, and letting a reference plane be a plane that includes the first direction and the second direction, the method comprising:
a step of acquiring inclination angles of the structure relative to the first direction in the reference plane, the inclination angles being measured at each of a plurality of different times at a plurality of measurement positions, the plurality of measurement positions being at different distances from a reference position in the first direction;
a step of estimating, with use of the inclination angles acquired in the step of acquiring inclination angles, a relationship between distance from the reference position in the first direction and displacement of the structure from the reference orientation in the reference plane at a position separated from the reference position by the distance, for each of the plurality of different times;
a step of specifying time-series values of displacement of the structure from the reference orientation at a specified position in the first direction with use of the relationship estimated in the step of estimating a relationship for each of the plurality of different times;
a step of acquiring time-series values of acceleration of the structure in the second direction measured at a specified measurement position in the first direction;
a step of extracting components having a frequency greater than or equal to a predetermined threshold value from a waveform expressed by the time-series values of acceleration acquired in the step of acquiring time-series values of acceleration;
a step of calculating an integral of the components extracted from the waveform in the step of extracting components to calculate time-series values of a fine fluctuation component of displacement of the structure in the second direction at the specified measurement position; and
a step of correcting the time-series values of displacement that were specified using the estimated relationships, by adding, to the time-series values of displacement specified in the step of specifying time-series values of displacement, the time-series values of a fine fluctuation component of displacement calculated in the step of calculating an integral.

8. (canceled)

9. (canceled)
